(19) United States
(12) Patent Application Publication
(10) Pub. No.: US 2009/0130845 A1
(43) Pub. Date: May 21, 2009

(54) DIRECT ELECTRODEPOSITION OF COPPER ONTO TA-ALLOY BARRIERS

(75) Inventors: Brett Baker-O'Neal, Sleepy Hollow, NY (US); Cyril Cabral, JR., Mahopac, NY (US); Hariklia Deligianni, Tenafly, NJ (US); James J. Kelly, Schenectady, NY (US); Min Zheng, Harrisburg, PA (US)

Correspondence Address: Connolly Bove Lodge & Hutz LLP, Suite 1100, 1875 Eye Street, NW, Washington, DC, 20006, US

(73) Assignee: International Business Machines Corporation, Armonk, NY (US)

(21) Appl. No.: 11/942,393

(22) Filed: Nov. 19, 2007

(51) Int. Cl. H01L 21/4763

(52) U.S. Cl. 438/656; 257/E21.495

(57) ABSTRACT

A method of depositing copper directly onto a tantalum alloy layer of an on-chip copper interconnect structure, which includes electrodepositing copper from a neutral or basic electrolyte onto a surface of a tantalum alloy layer, in which the tantalum alloy layer is deposited on a substrate of the on-chip copper interconnect structure, and in which the copper nucleates onto the surface of the tantalum alloy layer without use of a seed layer to form a copper conductor.

### BACKGROUND

1. Technical Field

The present disclosure relates to a method of depositing copper directly onto a tantalum (Ta) alloy layer of an on-chip copper interconnect structure, which includes electrodeposition of copper (Cu) from a neutral or basic electrolyte onto a surface of a Ta alloy layer, in which the Ta alloy layer is deposited on a substrate of the on-chip Cu interconnect structure, and in which the Cu nucleates onto the surface of the Ta alloy layer without use of a seed layer to form a Cu conductor. The direct deposition of Cu onto a Ta alloy eliminates the need and drawbacks of a deposited Cu seed layer for formation of a Cu conductor.

2. Discussion of the Background

Current technologies for fabricating on-chip copper interconnects rely on the use of a copper seed layer as a plating base for the subsequent copper electrodeposition reaction. This copper seed layer is typically deposited by physical vapor deposition (PVD), a vacuum deposition technique. The copper seed layer is deposited on top of a liner, usually a Ta/TaN (tantalum nitride) bilayer that is also deposited by PVD. The TaN acts as a diffusion barrier, preventing copper from diffusing into the dielectric and corrupting underlying silicon devices, such as semiconductor logic and memory devices.

The PVD-deposited copper seed layer has been found necessary for good adhesion of the electrodeposited Cu to the substrate, as well as for the subsequent successful filling of the feature with electrodeposited copper. Features filled with copper generally may include narrow metal lines, vias, and large pads. As feature sizes are scaled down for future technologies, obtaining good step coverage of the PVD Cu seed within the feature becomes increasingly difficult, particularly on the sidewalls. Incomplete or discontinuous seed coverage (which may be referred to a scaling) results in voids in the plated feature where the seed is absent and lower product yield. As a result, it may not be possible to obtain appreciable PVD Cu seed coverage in deep, high aspect ratio features, making it impossible to fill the feature with electrodeposited Cu.

The method of the present disclosure overcomes the difficulty of PVD Cu seed layer scaling by employing a Ta alloy layer instead of Ta alone as a liner. However, a TaN layer may be deposited and retained underneath the Ta alloy layer as a diffusion barrier layer. The alloying element in the Ta, which may include Cu, allows one to deposit directly onto the Ta-alloy surface if an appropriate plating chemistry is used (for example, a neutral or basic Cu plating electrolyte, such as those based on citrate or pyrophosphate salts). Other alloying elements that allow Cu to nucleate successfully onto the Ta alloy surface can be used as well, which may include the Pt group metals and the iron-group metals promote Cu nucleation when they are alloyed with Ta. The Ta alloy layer may be deposited by PVD or some other means of vacuum deposition, such as chemical vapor deposition for example.

Phase-in deposition, where a compositionally graded alloy film is intentionally deposited (a TaCu alloy that is Cu-rich at the surface is one such case) can be advantageously used to obtain good adhesion and nucleation of the Cu layer to the Ta alloy surface. After depositing the initial Cu layer onto the Ta alloy with a neutral or basic Cu electrolyte, a conventional acidic Cu electrolyte with the typical organic additives necessary to achieve good feature filling is used. Since the PVD Cu seed layer step is eliminated, the problem of incomplete or discontinuous Cu seed deposition is overcome.

### SUMMARY

Accordingly, an aspect of the present disclosure is overcomes the difficulty of PVD Cu seed layer scaling by directly depositing copper onto a Ta alloy layer of an on-chip copper interconnect structure. In particular, the method generally comprises:

electrodepositing copper from a neutral or basic electrolyte onto a surface of a tantalum alloy layer,

wherein the tantalum alloy layer is deposited on a substrate of the on-chip copper interconnect structure, and

wherein the copper nucleates onto the surface of the tantalum alloy layer without use of a seed layer to form a copper conductor.

Other objects and advantages of the present disclosure will become readily apparent by those skilled in the art from the following detailed description, in which it is shown and described only in the preferred embodiments, simply by way of illustration of the best mode. As will be realized, the disclosure is capable of other and different embodiments, and its several details are capable of modifications in various obvious respects, without departing from the intent of this disclosure. Accordingly, the description is to be regarded as illustrative in nature and not as restrictive.

### BRIEF DESCRIPTION OF THE DRAWINGS

FIG. 1 illustrates a graphic plot of the polarization behavior of TaCu alloy substrates with various Cu contents in an alkaline copper plating electrolyte.

FIG. 2 illustrates a graphic plot of the polarization behavior of TaCu, TaPt, and TaNi alloy substrates.

FIG. 3 shows several SEM micrographs of plated Cu on TaCu, TaPt, and TaNi alloys.

FIG. 4 shows the morphology of 20 nm of Cu deposited on Ta and TaCu alloys having various Cu contents.

FIGS. 5 and 6 show several cross-sectional views of Cu deposited onto TaCu alloys having various Cu contents.

### BEST AND VARIOUS MODES FOR CARRYING OUT THE DISCLOSURE

A more complete appreciation of the disclosure and many of the attendant advantages will be readily obtained, as the same becomes better understood by reference to the following detailed description when considered in connection with the accompanying drawings.

In the method of the disclosure, an electrolyte composition for achieving a high nuclei density of the electrodeposited Cu on the Ta alloy substrate may include, but is not limited to, one based on the copper salts of the citrate, ethylene diamine tetra-acetic acid (EDTA), pyrophosphate, or cyanide ion, for example. Such electrolyte chemistries may be generally known as “strike” baths, since they are capable of high nuclei densities when depositing on substrate surfaces that are otherwise difficult to plate.

For example, copper deposited at a current density from about 1 to about 5 mA/cm² from a room temperature citrate bath containing 0.1 M copper sulfate, 0.2 M sodium citrate, and 0.3 M boric acid in a pH range from about 9 to about 12 may be useful for this purpose. Alternatively, deposition may occur at a current density from about 10 to about 20 mA/cm² and 50° C. from a pyrophosphate bath containing 0.25 copper pyrophosphate, 1.0 M potassium pyrophosphate, and 0.4 M potassium phosphate at a pH of about 8.5 may also be used. Other examples of such baths may be found in the literature.

The thickness of the Ta alloy layer and/or diffusion barrier layer may range from about 1 to about 50 nm, depending on feature geometry and on the uniformity of the thickness distribution of the layer. Generally, a nominal thickness of the film may be applied to insure good coverage of the material in all features.

The alloying element in the Ta alloy may be include, but is not limited to, Fe, Ru, Os, Co, Rh, Ir, Ni, Pd, Pt, Cu, Ag, Au, and mixtures thereof. The Ta alloy is preferably one of TaCu, TaPt, or TaNi. When the Ta alloy is TaCu, the amount of Cu in the alloy may be 40 to 45 weight percent, as discussed below.

The alloying element may be present in the Ta alloy layer may range anywhere from about 0.1 to about 50 weight percent. Generally, it is desirable to keep the alloying element content as low as possible to maximize the liner properties of the Ta alloy. At the same time, a sufficient amount of the alloying element must be included to enable Cu electrodeposition on the surface of the alloy.

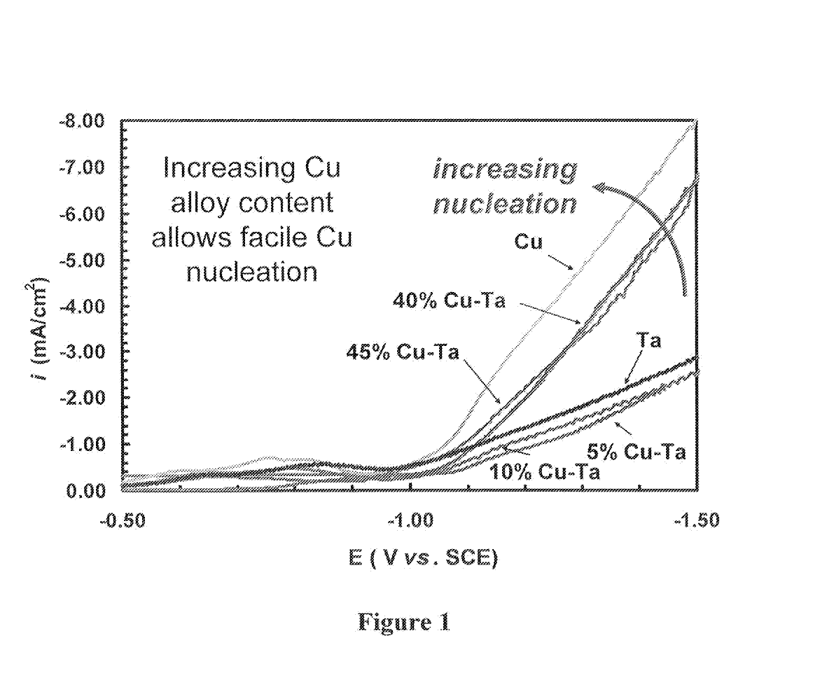

Turning to the figures of the disclosure, FIG. 1 shows the polarization behavior of copper deposition from a basic citrate electrolyte on various TaCu alloy substrates. The higher deposition currents on the 40 and 45% Cu containing TaCu alloys demonstrate that deposition proceeds more easily on these substrates than on the lower Cu content TaCu alloys and on pure Ta.

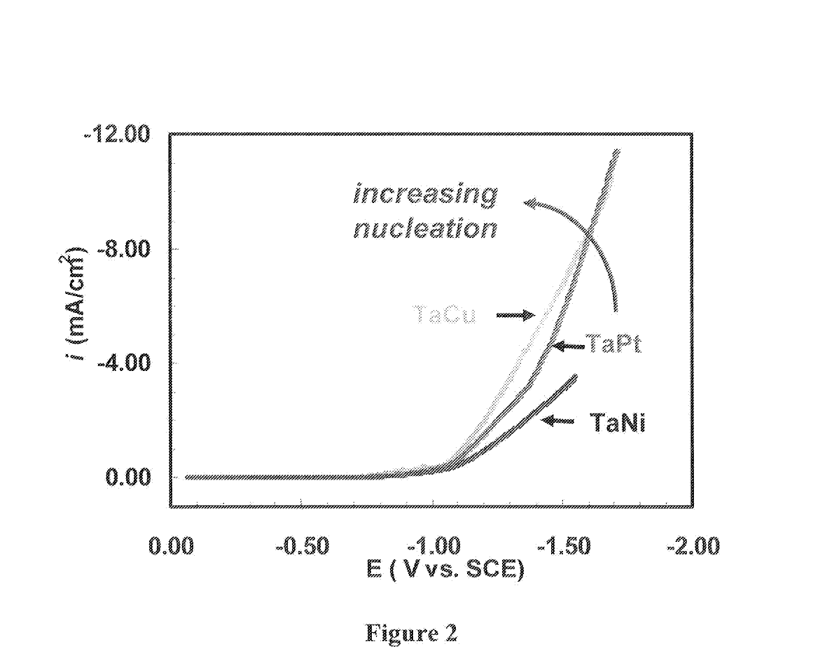

FIG. 2 shows the polarization behavior of copper deposition from a basic citrate electrolyte on Ta alloyed separately with 40% Cu, 20% Pt, and 20% Ni (in weight percent). Deposition occurs most easily on the TaCu alloy, followed by the TaPt alloy, and then the TaNi alloy, as shown by the current density behavior.

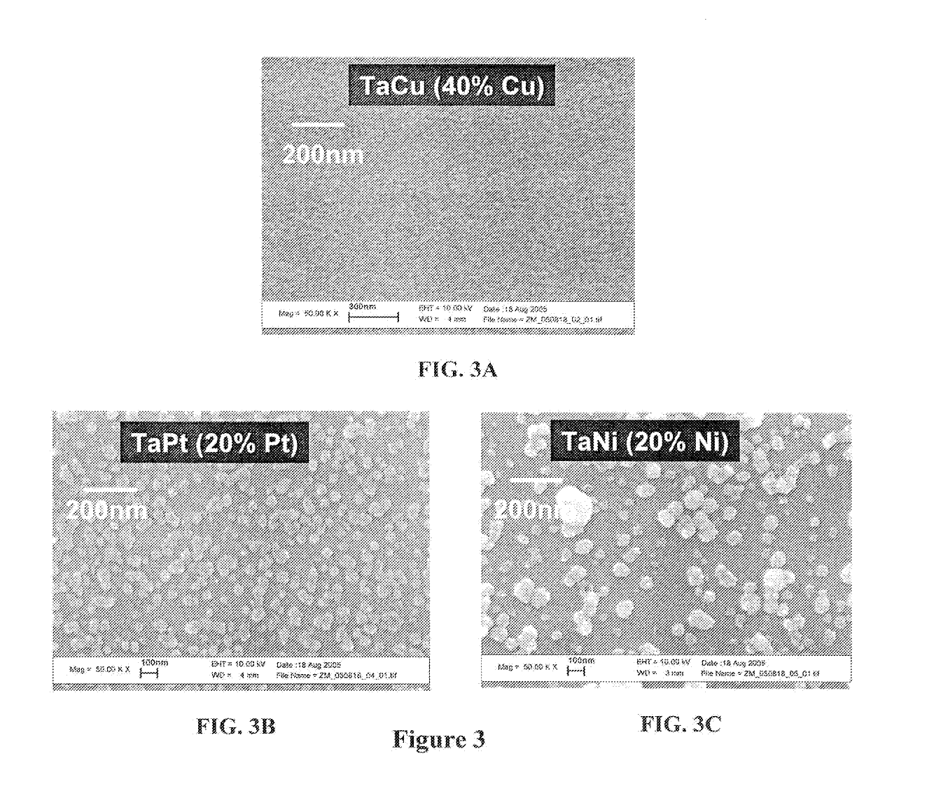

FIG. 3 shows a top down scanning electron microscope (SEM) image of 5 nm of Cu electrodeposited from a citrate bath on the same alloys as shown in FIG. 2. The highest nuclei density is observed for the TaCu alloy, followed by the TaPt alloy, and then the TaNi alloy. This is consistent with the current density trend observed in FIG. 2.

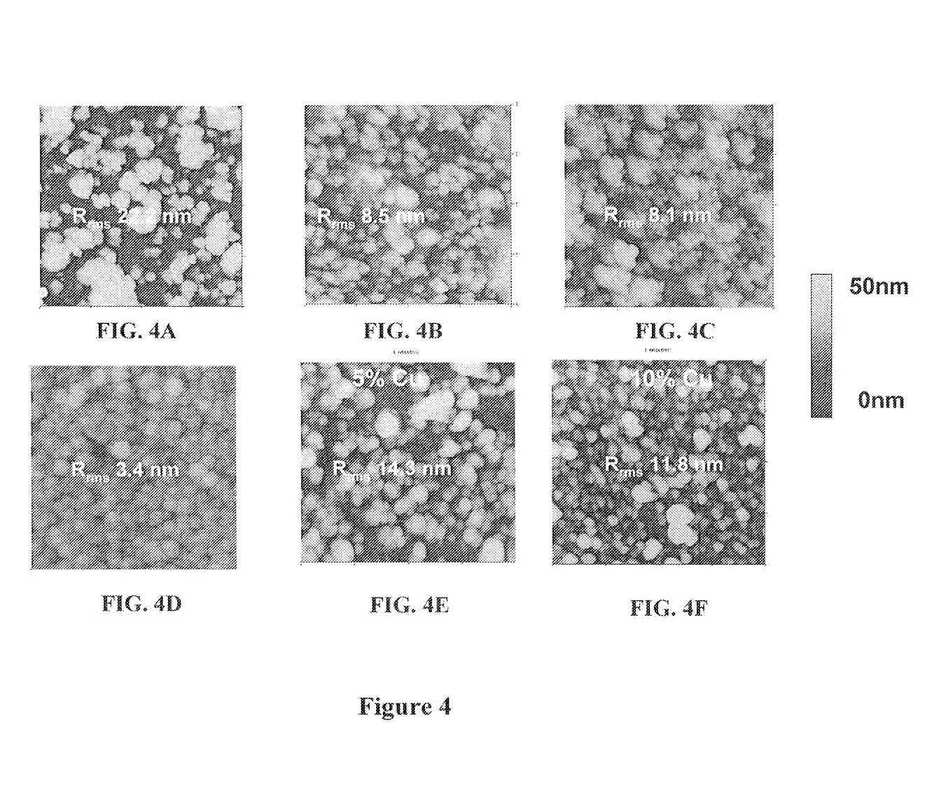

FIG. 4 shows the morphology of 20 nm of Cu electrodeposited from a citrate bath on various TaCu alloys as observed by atomic force microscopy (AFM). Root mean square (rms) values are shown for each deposit. Just 5% of Cu in Ta is effective in promoting the even nucleation of copper on the alloy surface from the point of view of the surface smoothness.

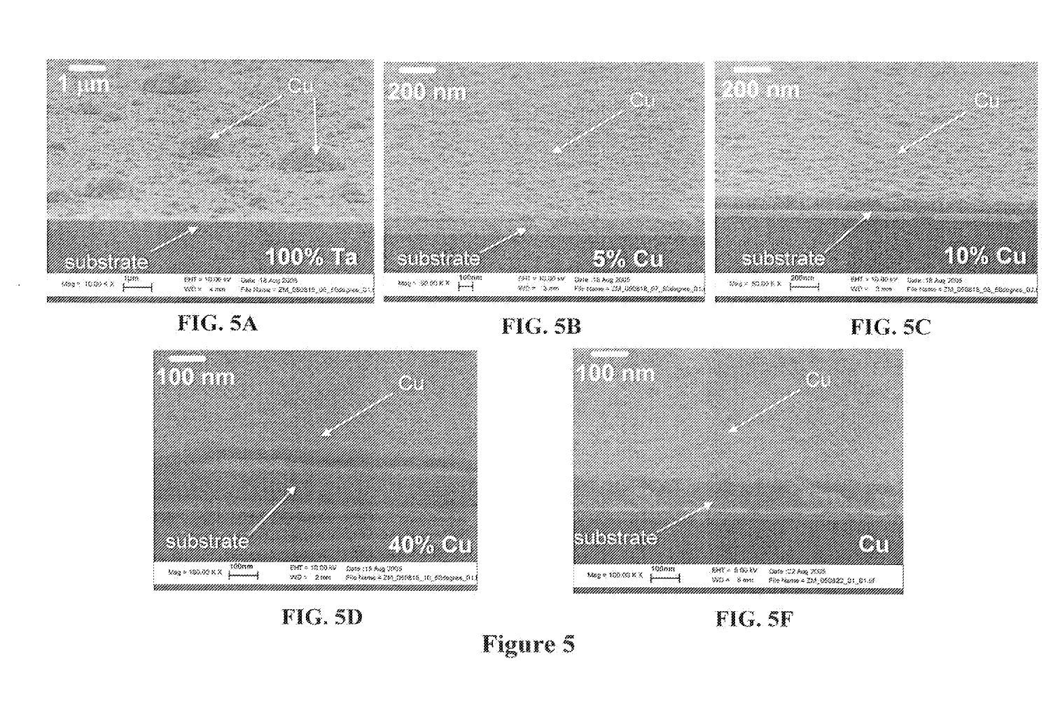

FIG. 5 shows several top down SEM images of copper nucleation on the alloy surface for various TaCu alloys. As observed by AFM in FIG. 4, just a 5% of Cu improves the nucleation density of the electrodeposited Cu on the TaCu surface.

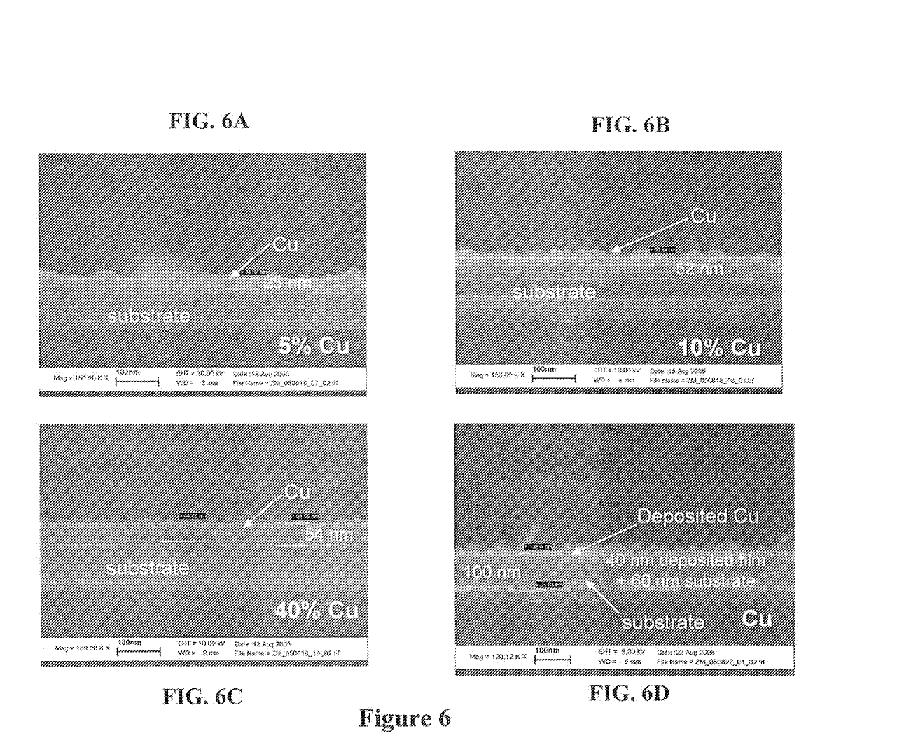

FIG. 6 shows several SEM cross sections of cleaved alloy substrates showing the electrodeposited Cu film on the alloy surface for TaCu alloys having 5%, 10%, 40%, Cu and pure Cu. As was the case in the previous two figures, the 5% Cu alloy has a surface roughness and morphology similar to that seen in the higher Cu alloys and Cu itself.

Obviously, numerous modifications and variations of the disclosure are possible in light of the above disclosure. It is therefore understood that within the scope of the appended claims, the disclosure may be practiced otherwise than as specifically described herein.

What is claimed is:

1. A method of depositing copper directly onto a tantalum alloy layer of an on-chip copper interconnect structure, the method comprising:
electrodepositing copper from a neutral or basic electrolyte onto a surface of a tantalum alloy layer,
wherein the tantalum alloy layer is deposited on a substrate of the on-chip copper interconnect structure, and
wherein the copper nucleates onto the surface of the tantalum alloy layer without use of a seed layer to form a copper conductor.

2. The method according to claim 1, wherein the alloying element in the Ta alloy is selected from the group consisting of Fe, Ru, Os, Co, Rh, Ir, Ni, Pd, Pt, Cu, Ag, Au, and mixtures thereof.

3. The method according to claim 1, wherein the amount of alloying element in the Ta alloy ranges from about 0.1 to about 50 weight percent.

4. The method according to claim 1, wherein the tantalum alloy is selected from the group consisting of TaCu, TaPt, and TaNi.

5. The method according to claim 1, wherein the tantalum alloy is TaCu.

6. The method according to claim 1, wherein the tantalum alloy is TaPt.

7. The method according to claim 1, wherein the tantalum alloy is TaNi.

8. The method according to claim 1, wherein the deposition current of the electrodeposition ranges from about 1 to about 5 mA/cm².

9. The method according to claim 1, wherein the deposition current of the electrodeposition ranges from about 10 to about 20 mA/cm².

10. The method according to claim 1, wherein the amount of copper in the tantalum alloy layer ranges from about 40 to about 45 weight percent.

11. The method according to claim 1, wherein a thickness of the tantalum alloy layer ranges from about 1 to about 50 nm.

12. The method according to claim 1, wherein the electrodeposition is at room temperature.

13. The method according to claim 1, wherein the electrodeposition is at 50° C.

14. The method according to claim 1, wherein the copper is deposited from a citrate bath comprising 0.1 M copper sulfate, 0.2 M sodium citrate, and 0.3 M boric acid.

15. The method according to claim 1, wherein the pH of the citrate bath ranges from about 9 to about 12.

16. The method according to claim 1, wherein the copper is deposited from a pyrophosphate bath comprising 0.25 copper pyrophosphate, 1.0 M potassium pyrophosphate, and 0.4 M potassium phosphate.

17. The method according to claim 1, wherein the pH pyrophosphate bath is at about 8.5.

18. The method according to claim 1, wherein the Ta alloy layer is deposited on the substrate by physical vapor deposition.

19. The method according to claim 1, wherein a TaN layer is deposited and retained underneath the Ta alloy layer as a diffusion barrier layer.

20. The method according to claim 1, wherein the on-chip copper interconnect is formed on a silicon device.
